(19) United States
(12) Patent Application Publication
(10) Pub. No.: US 2022/0028796 A1
(43) Pub. Date: Jan. 27, 2022

(54) SEMICONDUCTOR STRUCTURE AND FORMING METHOD THEREOF

(71) Applicant: CHANGXIN MEMORY TECHNOLOGIES, INC., Hefei (CN)

(72) Inventors: PING-HENG WU, Hefei (CN); Chih-Wei Chang, Hefei (CN)

(21) Appl. No.: 17/389,693

(22) Filed: Jul. 30, 2021

Related U.S. Application Data
(63) Continuation of application No. PCT/CN2021/095607, filed on May 24, 2021.

(30) Foreign Application Priority Data
Jul. 21, 2020 (CN) 202010704669.4

(51) Int. Cl. H01L 23/532; H01L 23/367; H01L 21/768

(52) U.S. Cl. CPC H01L 23/53266; H01L 21/76843; H01L 23/367

(57) ABSTRACT

A semiconductor structure and a forming method thereof are provided. The forming method of the semiconductor structure includes that: a wafer having a front surface and a back surface is provided, a conductive plug being provided in the wafer, the conductive plug extending from the front surface to the back surface and the conductive plug having a bottom surface located in the wafer; an etching process is performed on the back surface of the wafer to form a groove exposing at least the bottom surface of the conductive plug; and a functional layer covering the bottom surface of the conductive plug is formed.

### CROSS-REFERENCE TO RELATED APPLICATION

The present application is a continuation application of International Application No. PCT/CN2021/095607, filed on May 24, 2021, which claims priority to Chinese patent application No. 202010704669.4, filed on Jul. 21, 2020 and entitled “Semiconductor Structure and Forming Method thereof”. The contents of International Application No. PCT/CN2021/095607 and Chinese patent application No. 202010704669.4 are hereby incorporated by reference in their entireties.

### BACKGROUND

In the research and development process of a 3D chip structure, in order to enhance a heat conduction effect of a chip package, an element with good heat conduction performance, such as a pseudo-conductive plug, is usually placed in a wafer so as to conduct and dissipate heat at a certain position of the wafer.

In the forming process of the conductive plug, when the depth-to-width ratio of a groove for filling a conductive material and forming a protective film layer is large, a film layer formed by a deposition process and covering the bottom and sidewall of the groove has the problem of poor deposition, thereby causing a performance defect. In order to solve the performance defect, poorly deposited portions may be adjusted usually in the related art. However, there are some problems in the related art.

### SUMMARY

The present disclosure relates to the field of semiconductors, and provides a semiconductor structure and a forming method of the semiconductor structure.

In a first aspect, some embodiments of the present disclosure provide a forming method of the semiconductor structure, which may include that: a wafer having a front surface and a back surface is provided, a conductive plug being provided in the wafer, the conductive plug extending from the front surface to the back surface and the conductive plug having a bottom surface located in the wafer; an etching process is performed on the back surface of the wafer to form a groove exposing at least the bottom surface of the conductive plug; and a functional layer covering the bottom surface of the conductive plug is formed.

In a second aspect, some embodiments of the present disclosure further provide a semiconductor structure, which may include: a wafer having a front surface and a back surface, a conductive plug being provided in the wafer, the conductive plug extending from the front surface to the back surface and the conductive plug having a bottom surface located in the wafer; a groove, having a top opening located on a plane where the back surface of the wafer is and exposing at least the bottom surface of the conductive plug; and a functional layer, covering the bottom surface of the conductive plug.

### BRIEF DESCRIPTION OF THE DRAWINGS

One or more embodiments are illustrated by way of example in the figures in the corresponding drawings, which are not construed as limiting the embodiments, and unless otherwise indicated, the figures in the drawings do not constitute a scale restriction.

FIGS. 1-4 are schematic structure diagrams corresponding to various operations of a forming method of a semiconductor structure.

FIGS. 5-12 are schematic structure diagrams corresponding to various operations of a forming method of a semiconductor structure according to an embodiment of the present disclosure.

FIG. 13 is a schematic structure diagram of a semiconductor structure according to another embodiment of the present disclosure.

### DETAILED DESCRIPTION

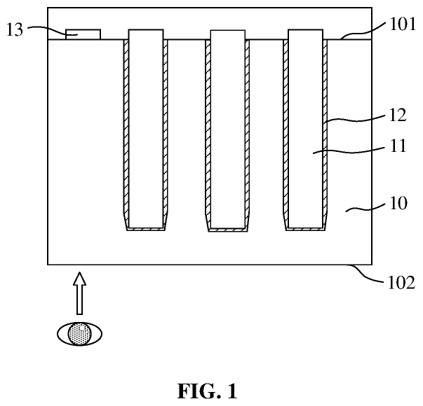

Referring to FIG. 1, a semiconductor structure includes: a wafer 10, a protective layer 12, and a marking pattern 13. The wafer 10 has a front surface 101 and a back surface 102 opposite to the front surface 101. A conductive plug 11 is provided in the wafer 10. The conductive plug 11 extends from the front surface 101 to the back surface 102. A bottom surface of the conductive plug 11 is located in the wafer 10. The protective layer 12 covers the bottom surface and sidewall of the conductive plug 11. The marking pattern 13 is located on the front surface 101 of the wafer.

The protective layer 12 may be a laminated structure. The protective layer 12 may include a barrier layer cladding the bottom surface and sidewall of the conductive plug 11 and a dielectric layer cladding the surface of the barrier layer. The barrier layer is configured to prevent metal ions in the conductive plug 11 from migrating into the wafer 10. The dielectric layer is configured to prevent electric leakage of the conductive plug 11.

As the depth-to-width ratio of a groove accommodating the conductive plug 11 and the protective layer 12 increases constantly, there is a problem of poor deposition at the bottom of the groove during the process of forming the protective layer 12 through deposition, and the problem of poor deposition is more serious in a bottom corner region which further includes a partial sidewall of the groove. The problem of poor deposition may cause the protective layer 12 unable to achieve a better protective effect, resulting in performance defect of the semiconductor structure, such as diffusion of metal ions in the conductive plug 11 and electric leakage of the conductive plug 11.

In addition, since the marking pattern 13 is located on the front surface 101, it is necessary to recognize and utilize the marking pattern 13 located on the front surface 101 when processing the back surface 102 of the wafer 10, which has a certain difficulty and a large alignment error.

In order to solve the technical problem of poor deposition, and in order to ensure that the conductive plug 11 has a good heat dissipation effect, a certain process is usually selected to be performed on the bottom surface and sidewall of the conductive plug 11 in the current processes. Specific operations are as follows.

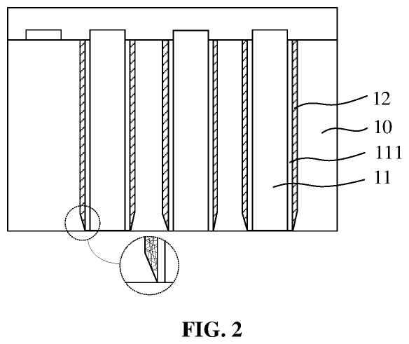

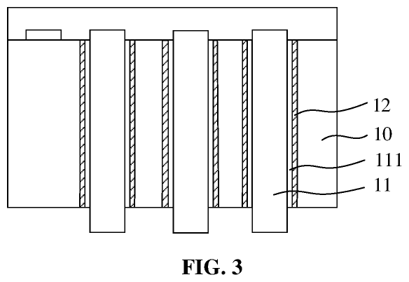

Referring to FIG. 2, a first planarization process is performed to remove the wafer 10 on the bottom surface of the conductive plug 11 to expose the bottom surface of the conductive plug 11. Referring to FIG. 3, an etching process is performed to remove the protective layer 12 covering the partial sidewall of the conductive plug 11 and the wafer 10 between the adjacent conductive plugs 11 to expose the partial sidewall of the conductive plug 11. The surface of this partial sidewall of the conductive plug 11 usually has a problem of poor deposition of the protective layer 12.

Since the removal rate of the planarization process is usually greater than that of the etching process, the bottom surface of the conductive plug 11 is exposed by adopting the planarization process, and the partial sidewall of the conductive plug 11 is exposed by adopting the etching process, so that the period of the whole process flow can be shortened. However, the planarization process generates a certain pulling stress. When the planarization process is performed on the basis of the bottom surface of the conductive plug 11, the pulling stress is exerted on the conductive plug 11, so that the conductive plug 11 continuously exerts a compressive stress on a peripheral structure during the process, thereby causing the conductive plug 11 to be separated from the protective layer 12, forming a first gap 111, and causing the protective layer 12 to be partially cracked.

The debris of the cracked protective layer 12 may fall into the first gap 111. When the protective layer 12 and the conductive plug 11 are caused to be sealed and joined again, the debris of the protective layer 12 may cause the protective layer 12 and the conductive plug 11 not to be effectively sealed and joined. In addition, when the protective layer 12 and the conductive plug 11 are caused to be sealed and joined, the presence of debris from the protective layer 12 may cause the problem of stress concentration, thereby causing damage to the intact protective layer 12.

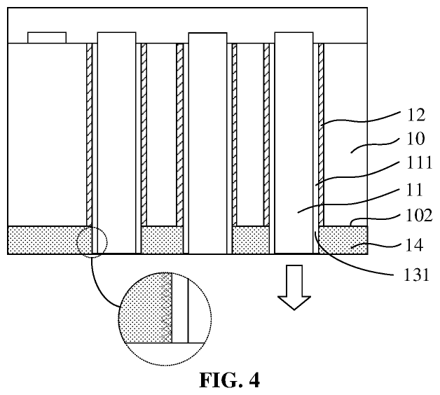

Referring to FIG. 4, a dielectric material is deposited on the back surface 102 of the wafer 10, and a second planarization process is performed to form the dielectric layer 14 exposing the bottom surface of the conductive plug 11.

Since the dielectric layer 14 exposes the bottom surface of the conductive plug 11, the second planarization process is further performed on the basis of the bottom surface of the conductive plug 11, that is, the second planarization process further pulls the conductive plug 11, resulting in a second gap 131 between the conductive plug 11 and the dielectric layer 14, and leading to the cracking of the partial dielectric layer 14 adjacent to the conductive plug 11.

In addition, the sidewall of the conductive plug 11 is protected by means of cladding, while the bottom surface of the conductive plug 11 is exposed to conduct heat, so that the conductive plug 11 is damaged without covering with other film layers, and the exposure of the conductive plug 11 has a risk of electric leakage.

In order to solve the problems, the embodiments of the present disclosure provide a semiconductor structure and a forming method of the semiconductor structure. When a bottom surface of a conductive plug located in a wafer is exposed, a groove exposing the bottom surface of the conductive plug is formed by adopting an etching process instead of a planarization process, so that damage to the conductive plug and structures around the conductive plug caused by a pulling stress of the planarization process is avoided, thereby ensuring good performance of the semiconductor structure.

In addition, a groove exposes the bottom surface of any of the conductive plugs, so that the bottom surface of any conductive plug can be covered by a functional layer, and performance defect of the semiconductor structure caused by the fact that the bottom surfaces of some conductive plugs are not covered by the functional layer can be avoided.

To more clarify the objects, technical solutions, and advantages of the embodiments of the present disclosure, various embodiments of the present disclosure will be described below in combination with the accompanying drawings. However, those of ordinary skill in the art will appreciate that in various embodiments of the present disclosure, numerous technical details are set forth in order to provide readers with a better understanding of the present disclosure. However, even without these technical details and various changes and modifications based on the following embodiments, the claimed technical solution of the present disclosure may be implemented.

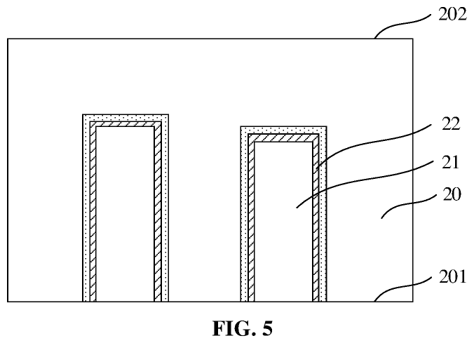

FIGS. 5-12 are schematic structure diagrams corresponding to various operations of a manufacturing method of a semiconductor structure according to an embodiment of the present disclosure.

Referring to FIG. 5, a wafer 20 is provided. The wafer 20 has a front surface 201 and a back surface 202 opposite to the front surface 201. A conductive plug 21 is provided in the wafer 20. The conductive plug 21 extends from the front surface 201 to the back surface 202. A bottom surface of the conductive plug 21 is located in the wafer 20.

In the present embodiment, in a direction perpendicular to the back surface 202 of the wafer 20, a first preset distance is provided between the back surface 202 of the wafer 20 and the bottom surface of the conductive plug 21. The first preset distance is obtained by performing a thinning process and a planarization process on the back surface 202 of the wafer 20. The planarization process has a lower removal rate and a higher surface machining quality than the thinning process, and may be used for removing deeper scratches formed during the thinning process.

At present, the planarization process is that a polishing head exerts pressure on a polishing pad and drives the polishing pad to rotate, so that grinding liquid between the polishing pad and the wafer can be uniformly distributed on the surface of the wafer, chemical components in the grinding liquid can generate a chemical reaction with materials on the surface of the wafer, insoluble substances are converted into soluble substances, or substances with high hardness are softened. Then, these chemical reactants are removed by micro-mechanical friction of abrasive particles in the grinding fluid to achieve the purpose of planarization.

When the abrasive particles are rubbed on the surface of a certain structure, a certain pulling stress is exerted on the structure. When a certain structure is an independent part, since materials of the adjacent other structures are different from a material of this certain structure, a good force conduction cannot be achieved, and the problem of stress concentration may exist when a force is performed on this certain structure. Therefore, the adjacent other structures may be squeezed by this certain structure, so that this certain structure is separated from the adjacent other structures, and the adjacent other structures are damaged, e.g. crushed.

It should be noted that the pulling stress caused by the abrasive particles is reduced gradually in a direction away from the friction surface. Therefore, the distance between the bottom surface of the conductive plug 21 and the back surface 202 of the wafer 20 is larger than or equal to the first preset distance, so that the conductive plug 21 is favorably prevented from being affected by the pulling stress caused by the planarization process, the conductive plug 21 is prevented from separating from the surrounding film layer, and the surrounding film layer is prevented from cracking.

After the wafer 20 is provided, the back surface 202 of the wafer 20 needs to be etched to form a groove exposing the bottom surface of the conductive plug 21. The groove forming process includes the following operations.

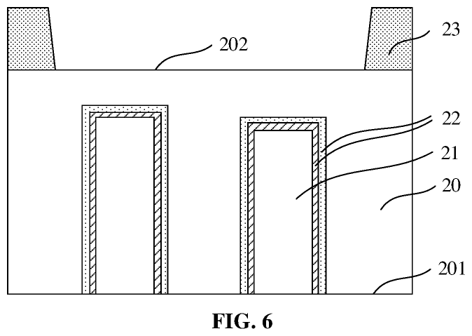

Referring to FIG. 6, a patterned mask layer 23 is formed on the back surface 202 using a mask. An orthographic projection of the bottom surface of the conductive plug 21 is located in an orthographic projection of an opening of the mask layer 23 in a direction perpendicular to the back surface 202.

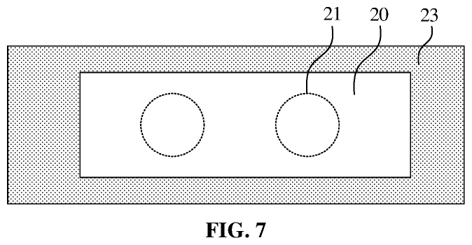

In the present embodiment, a plurality of conductive plugs 21 are provided in the wafer 20 for conducting heat. The conductive plugs 21 may be formed by Through Silicon Via (TSV). The mask layer 23 has a single opening. Referring to FIG. 7, the orthographic projection of the bottom surface of any conductive plug 21 is located in the orthographic projection of the single opening, so that the manufacturing difficulty of the mask is reduced.

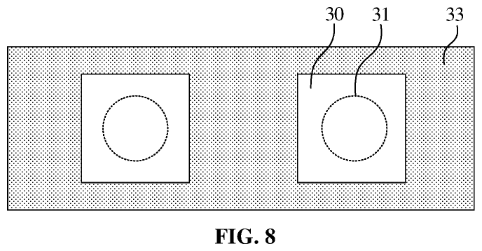

In other embodiments, referring to FIG. 8, the mask layer 33 has a plurality of openings, and the orthographic projection of one or more conductive plugs 31 is located in the orthographic projection of one opening, so that when other intermediate structures are provided between adjacent conductive plugs 31, and when the wafer 30 is etched with the opening to form a groove exposing the bottom surfaces of the conductive plugs 31, the intermediate structures cannot be exposed or damaged.

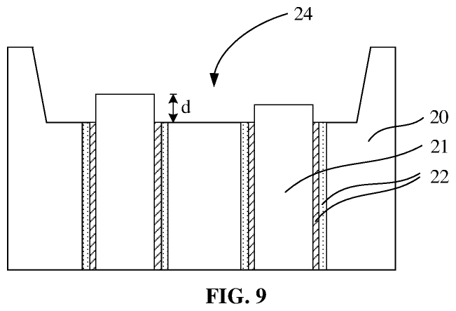

Referring to FIG. 9, an etching process is performed on the back surface 202 of the wafer 20 to form a groove 24 exposing at least the bottom surface of the conductive plug 21. The mask layer is removed after the groove 24 is formed.

In the present embodiment, the heights of the bottom surfaces of the plurality of conductive plugs 21 are different in a direction perpendicular to the back surface 202 of the wafer 20, and the groove 24 exposes the bottom surface of any of the conductive plugs 21. Thus, it is advantageous to ensure that the bottom surface of each conductive plug 21 can be covered by the functional layer in order to achieve the effects of the functional layer, e.g. protective isolation.

In the present embodiment, the groove 24 further exposes a partial sidewall of the conductive plug 21, so that the subsequently formed functional layer may further cover the partial sidewall of the conductive plug 21, thereby compensating for poor deposition of the protective layer 22 on the partial sidewall of the conductive plug 21, and further improving the performance of the semiconductor structure.

In the present embodiment, a height difference d between the bottom surface of the groove 24 and the bottom surface of the conductive plug 21 is 2-10 nm, e.g. 4 nm, 6 nm or 8 nm. Thus, it is advantageous to ensure that the subsequently formed functional layer can completely cover a corner region of the conductive plug 21, i.e. a sidewall region of the conductive plug 21 with the poorly deposited protective layer 22, thereby ensuring that the semiconductor structure has good performance. In addition, the size of the height difference d is limited, so that the functional layer material can better cover the sidewall of the conductive plug 21 when the functional layer is subsequently filled, it can be ensured that the region between the adjacent conductive plugs 21 is filled with the functional layer material, the phenomenon of sealing in advance when filling occurs due to a large depth-to-width ratio of the groove between the adjacent conductive plugs 21 is avoided, and it is ensured that the functional layer material has a better filling effect.

In the present embodiment, the bottom surface and sidewall of the conductive plug 21 are covered with a protective layer 22. In the process operation of forming the groove 24, the etching process further serves to remove the protective layer 22 on the bottom surface and partial sidewall of the conductive plug 21 to expose the bottom surface and partial sidewall of the conductive plug 21. Thus, it is advantageous to ensure that the functional layer can be uniformly coated on the surface of the conductive plug 21 to realize the preset performance of the functional layer.

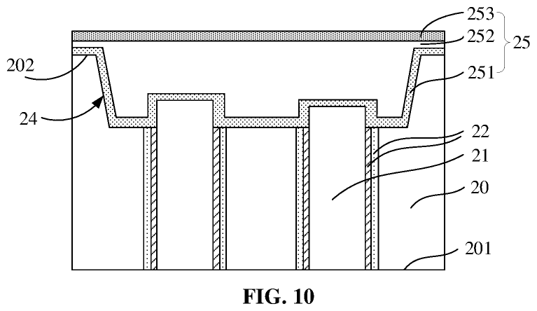

Before the protective layer 22 is removed, the protective layer 22 may be cracked, the surface of the cracked protective layer 22 far away from the conductive plug 21 usually assumes an uneven state, and the functional layer is coated on the uneven surface, so that the situation that the functional layer is not uniformly coated and the preset performance cannot be realized easily occurs. In addition, the protective layer 22 may be separated from the conductive plug 21. At this moment, the conductive plug 21 has poor structural stability, i.e. the conductive plug may vibrate along with the movement of the semiconductor structure. The protective layer 22 is removed and the functional layer is formed on the surface of the conductive plug 21, so that the conductive plug 21 can be fixed, the structural stability of the conductive plug 21 is improved, and damage to the functional layer caused by the vibration of the conductive plug 21 is avoided, thereby further ensuring that the functional layer can realize the preset performance. Referring to FIG. 10, a functional layer 25 covering the conductive plug 21 is formed.

In the present embodiment, after the groove 24 is formed, a barrier layer 251, a dielectric layer 252, and a bonding layer 253 are formed in sequence to constitute the functional layer 25. The barrier layer 251 is configured to block metal ions in the conductive plug 21 from migrating into the wafer 20 and the dielectric layer 252. The dielectric layer 252 is configured to prevent the electric leakage of the conductive plug 21. The bonding layer 253 is configured to perform a fusion bonding process so as to realize connection and packaging of a plurality of semiconductor structures.

In the present embodiment, before the bonding layer 253 is formed, a planarization process is required to be performed on the dielectric layer 252, so as to ensure that the bonding layer 253 can be formed on a flat surface, thereby enabling effective connection between different semiconductor structures without specially providing a unique bonding structure for objects to be mutually connected.

In order to prevent the planarization process of the dielectric layer 252 from affecting the conductive plug 21, the protective layer 22 covering the conductive plug 21, and the barrier layer 251, a distance between the surface of the dielectric layer 252 away from the barrier layer 251 and the bottom surface of the conductive plug 21 should be greater than or equal to a second preset distance in a direction perpendicular to the surface of the dielectric layer 252. The size of the second preset distance is related to the material of the dielectric layer 252 and the material of the barrier layer 251. In particular, as the stress transferring capacities of the material of the dielectric layer 252 and the material of the barrier layer 251 are stronger, the second preset distance is larger, so that a greater pulling stress is prevented from acting on the conductive plug 21.

In the present embodiment, the functional layer 25 covers the bottom surface of the conductive plug 21, so that the conductive plug 21 is prevented from being pulled by a larger stress in the subsequent application process, and a risk of poor chip quality caused by the stress pulling is avoided. In addition, it is advantageous to avoid undesired electric conduction of the conductive plug 21.

In the present embodiment, the material of the barrier layer 251 includes silicon carbonitride, or includes a tantalum layer and a tantalum nitride layer which are stacked in sequence. The tantalum layer covers the bottom surface of the conductive plug 21, and the tantalum nitride layer covers the tantalum layer. The material of the dielectric layer 252 includes at least one of silicon oxide, silicon nitride, or silicon oxynitride.

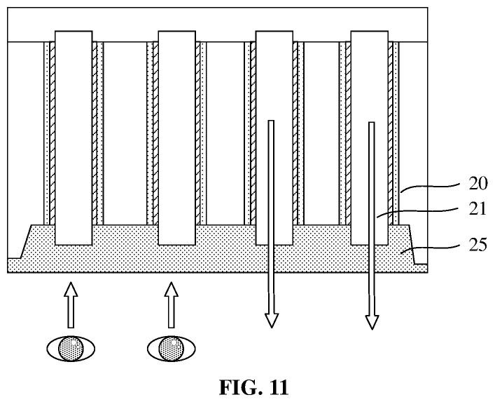

Referring to FIG. 11, in the present embodiment, the heat dissipation performance of the functional layer 25 may be superior to that of the wafer 20. Thus, the heat of the front surface 201 of the wafer 20 can be conducted through the conductive plug 21, and can be dissipated from the back surface 202 of the wafer 20 through the functional layer 25, so that the heat of the front surface 201 of the wafer 20 is prevented from being continuously accumulated, and components arranged on the front surface 201 are further prevented from being damaged by high heat, most heat of the front surface 201 of the wafer 20 is prevented from being dissipated in the wafer 20 and components in the wafer 20 are prevented from being damaged by high heat, thereby ensuring good performance of the semiconductor structure.

The functional layer 25 may include a plurality of materials. The heat dissipation performance of at least one material in the functional layer 25 is superior to that of the wafer 20.

In the present embodiment, the functional layer 25 covers not only the bottom surface of the conductive plug 21, but further the partial sidewall of the conductive plug 21, so that the contact area between the functional layer 25 and the conductive plug 21 can be increased, thereby accelerating the conduction rate of heat transferred from the conductive plug 21 to the functional layer 25, and ensuring that the heat of the front surface 201 can be dissipated at a higher rate.

In the present embodiment, after the functional layer 25 is formed, since the functional layer 25 does not block the sight line, alignment positioning may be performed through the bottom surface of the conductive plug 21 when the back surface of the wafer 20 is processed, thereby improving alignment accuracy of the processing. Preferably, the transparency of the functional layer 25 may be higher than that of the wafer 20.

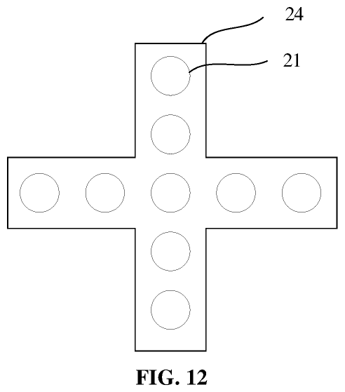

In the present embodiment, referring to FIG. 12, the conductive plug 21 and the groove 24 are arranged in a marking pattern. In other embodiments, the conductive plug or the groove is a marking pattern.

In the present embodiment, when a bottom surface of a conductive plug located in a wafer is exposed, a groove exposing the bottom surface of the conductive plug is formed by adopting an etching process instead of a planarization process, so that damage to the conductive plug and film layers and structures around the conductive plug caused by a pulling stress of the planarization process is avoided, thereby ensuring good performance of the semiconductor structure.

Correspondingly, an embodiment of the present disclosure further provides a semiconductor structure which may be manufactured by adopting the above forming method of the semiconductor structure.

Referring to FIG. 10, a semiconductor structure includes: a wafer 20, a groove 24, and a functional layer 25. The wafer 20 has a front surface 201 and a back surface 202 opposite to the front surface 201. A conductive plug 21 is provided in the wafer 20. The conductive plug 21 extends from the front surface 201 to the back surface 202. A bottom surface of the conductive plug 21 is located in the wafer 20. The groove 24 has a top opening located on a plane where the back surface 202 of the wafer 20 is. The groove 24 exposes at least the bottom surface of the conductive plug 21. The functional layer 25 covers the bottom surface of the conductive plug 21.

In the present embodiment, the groove 24 exposes the bottom surface and a partial sidewall of the conductive plug 21, and the functional layer 25 covers the bottom surface and the partial sidewall of the conductive plug 21.

In the present embodiment, a height difference between the bottom surface of the groove 24 and the bottom surface of the conductive plug 21 is 2-10 nm, e.g. 3 nm, 5 nm or 7 nm, in a direction perpendicular to the back surface 202 of the wafer 20.

In the present embodiment, the functional layer 25 is a laminated structure. The laminated structure 25 includes a barrier layer 251 covering the bottom surface of the conductive plug 21 and a dielectric layer 252 covering the barrier layer 251. The barrier layer 251 is configured to block metal ions in the conductive plug 21 from migrating into the dielectric layer 252.

Illustratively, the material of the barrier layer 251 includes silicon carbonitride, or the barrier layer 251 includes a tantalum layer and a tantalum nitride layer which are stacked in sequence. The tantalum layer covers the bottom surface of the conductive plug 21, and the tantalum nitride layer covers the tantalum layer.

In the present embodiment, the heat dissipation performance of the functional layer 25 is superior to that of the wafer 20. The transparency of the functional layer 25 is higher than that of the wafer 20. The conductive plug 21 and the groove 24 are arranged in a marking pattern.

In the present embodiment, the conductive plug is located in the groove and is covered by the functional layer, so that the conductive plug can be prevented from being affected by a pulling stress, the occurrence of electric leakage is avoided, and it is advantageous to ensure that the semiconductor structure has good performance.

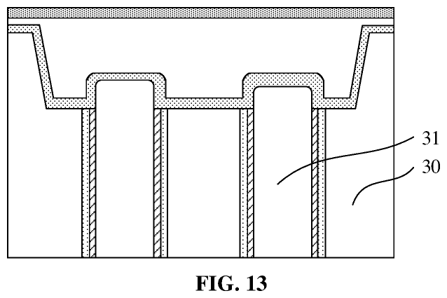

Another embodiment of the present disclosure further provides a semiconductor structure. Unlike the previous embodiment, in the present embodiment, bottom surfaces of a plurality of conductive plugs have the same height, and the bottom surfaces of the conductive plugs have rounded corners. Reference will now be made in detail to FIG. 13. FIG. 13 is a schematic structure diagram of a semiconductor structure according to another embodiment of the present disclosure. The same or corresponding parts as those of the previous embodiment may be referred to in the corresponding description of the previous embodiment. Descriptions of this embodiment are omitted hereinafter.

Referring to FIG. 13, the semiconductor structure includes a plurality of conductive plugs 31. Bottom surfaces of the plurality of conductive plugs 31 have the same height in a direction perpendicular to the surface of a wafer 30. In addition, a corner between the bottom surface of the conductive plug 31 and a sidewall is rounded.

The present embodiment provides a new semiconductor structure.

It will be appreciated by those of ordinary skill in the art that the various embodiments described above are specific embodiments for implementing the present disclosure and that various changes in form and details may be made in practice without departing from the spirit and scope of the present disclosure. Any person skilled in the art can make various changes and modifications without departing from the spirit and scope of the present disclosure, and therefore the scope of protection of the present disclosure should be determined by the scope of the claims.

1. A forming method of a semiconductor structure, comprising:
providing a wafer having a front surface and a back surface, a conductive plug being provided in the wafer, the conductive plug extending from the front surface to the back surface and the conductive plug having a bottom surface located in the wafer;
performing an etching process on the back surface of the wafer to form a groove exposing at least the bottom surface of the conductive plug; and
forming a functional layer covering the bottom surface of the conductive plug.

2. The forming method of claim 1, further comprising: performing a planarization process on the back surface of the wafer before performing the etching process.

3. The forming method of claim 1, wherein a plurality of conductive plugs are provided in the wafer, heights of bottom surfaces of the plurality of conductive plugs are different in a direction perpendicular to the back surface of the wafer, and the groove exposes the bottom surface of any of the conductive plugs.

4. The forming method of claim 1, wherein the groove further exposes a partial sidewall of the conductive plug, and the functional layer is further formed on the partial sidewall of the conductive plug in a process step of forming the functional layer.

5. The forming method of claim 1, wherein the bottom surface of the conductive plug is covered with a protective layer, and the etching process further serves to remove the protective layer in a process step of forming the groove.

6. The forming method of claim 1, wherein the functional layer comprises a barrier layer covering the bottom surface of the conductive plug and a dielectric layer filling the groove, the barrier layer being configured to block metal ions in the conductive plug from migrating into the dielectric layer.

7. The forming method of claim 6, wherein a material of the dielectric layer comprises at least one of silicon dioxide, silicon nitride, or silicon oxynitride, and a material of the barrier layer comprises silicon carbonitride.

8. The forming method of claim 1, wherein the functional layer comprises a bonding layer for performing a fusion bonding process.

9. A semiconductor structure, comprising:
a wafer having a front surface and a back surface, a conductive plug being provided in the wafer, the conductive plug extending from the front surface to the back surface and the conductive plug having a bottom surface located in the wafer;
a groove, having a top opening located on a plane where the back surface of the wafer is and exposing at least the bottom surface of the conductive plug; and
a functional layer, covering the bottom surface of the conductive plug.

10. The semiconductor structure of claim 9, wherein the groove exposes the bottom surface and a partial sidewall of the conductive plug, and the functional layer covers the bottom surface and the partial sidewall of the conductive plug.

11. The semiconductor structure of claim 10, wherein a height difference between a bottom surface of the groove and the bottom surface of the conductive plug is 2-10 nm in a direction perpendicular to the back surface of the wafer.

12. The semiconductor structure of claim 9, wherein the functional layer is a laminated structure, the laminated structure comprises a barrier layer covering the bottom surface of the conductive plug and a dielectric layer filling the groove, and the barrier layer is configured to block metal ions in the conductive plug from migrating into the dielectric layer.

13. The semiconductor structure of claim 12, wherein a material of the barrier layer comprises silicon carbonitride, or the barrier layer comprises a tantalum layer and a tantalum nitride layer which are stacked in sequence, the tantalum layer covers the bottom surface of the conductive plug, and the tantalum nitride layer covers the tantalum layer.

14. The semiconductor structure of claim 9, wherein the conductive plug and the groove are arranged in a marking pattern.
